(19) United States
(12) Patent Application Publication
(10) Pub. No.: US 2013/0295783 A1
(43) Pub. Date: Nov. 7, 2013

(54) CIRCUIT BOARD ASSEMBLY WITH SHIELDING MEMBER

(71) Applicants: Hong Fu Jin Precision Industry (WuHan) Co., Ltd., (US); HON HAI PRECISION INDUSTRY CO., LTD., New Taipei (TW)

(72) Inventors: BIAO ZENG, Wuhan (CN); XIANG ZHANG, Wuhan (CN); HENG TAO, Wuhan (CN); YUAN-TING GUO, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/715,034

(22) Filed: Dec. 14, 2012

(30) Foreign Application Priority Data
May 2, 2012 (CN) 201210131727.4

(51) Int. Cl. H05K 1/14

(52) U.S. Cl. CPC H05K 1/14
USPC 439/55

(57) ABSTRACT

A circuit board assembly includes a circuit board, a latch member attached to the circuit board, and a protective shielding member for accommodating the circuit board and the latch member. The circuit board includes a main board and a connector attached to the main board. At least one mounting hole is defined in the main board. At least one pin protrudes from the main board. The latch member includes a main panel abutting the main board, at least one engaging post engaging with the at least one mounting hole, and a covering portion for covering the at least one pin. Main portions of the main board and the main panel are received in the shielding member. The connector and the covering portion are exposed on the outside of the shielding member.

### BACKGROUND

1. Technical Field

The present disclosure relates to a circuit board assembly with a shielding member.

2. Description of Related Art

A typical circuit board assembly includes a master circuit board and a plurality of slave circuit boards connected to the master circuit board via connectors, thereby enhancing data processing ability of the master circuit board. However, such typical circuit boards lack any shielding and are easily damaged.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a circuit board assembly in accordance with an embodiment.

FIG. 2 is similar to FIG. 1, but viewed from another aspect.

FIG. 3 is an assembled view of the circuit board assembly of FIG. 1.

FIG. 4 is an assembled view of the circuit board assembly of FIG. 2.

### DETAILED DESCRIPTION

The disclosure is illustrated by way of example and not by way of limitation. In the figures of the accompanying drawings, like references indicate similar elements. It should be noted that references to “an” or “one” embodiment in this disclosure are not necessarily to the same embodiment, and such references mean “at least one.”

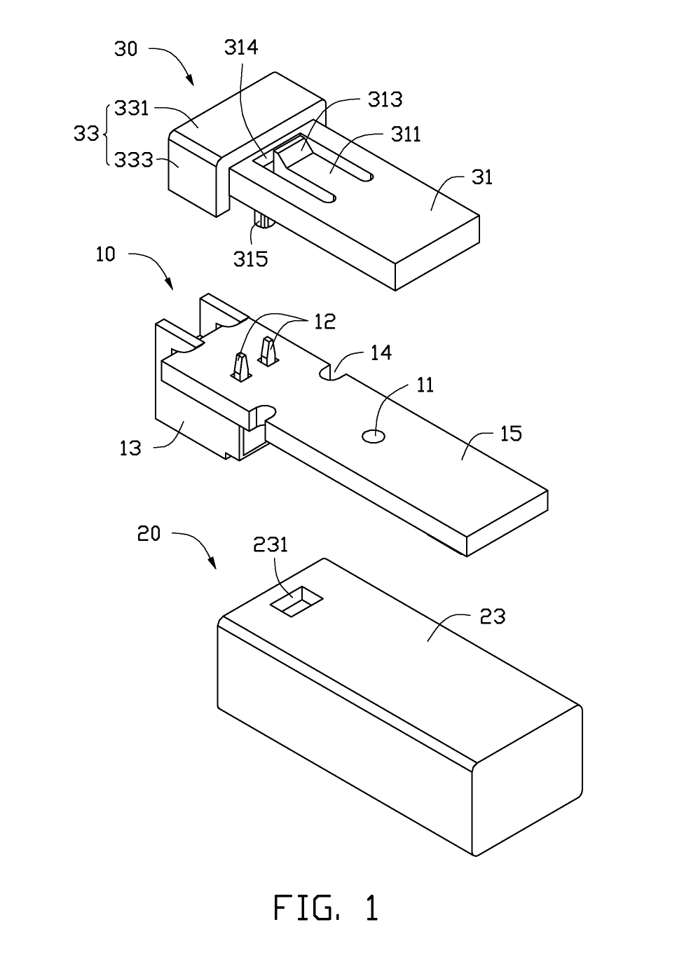

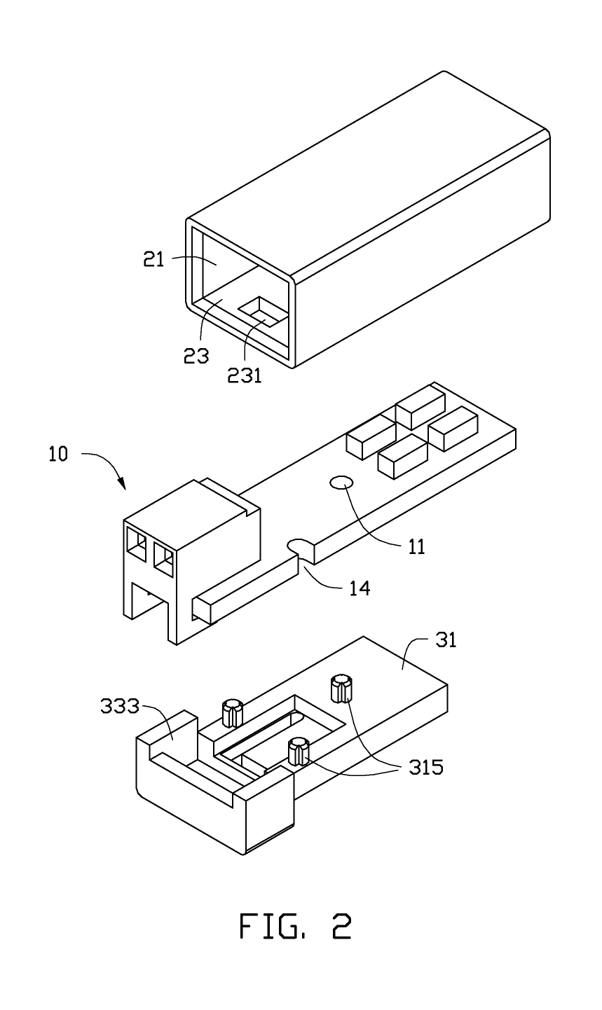

Referring to FIGS. 1 and 2, an embodiment of a circuit board assembly includes a circuit board 10, a shielding member 20, and a latch member 30.

The circuit board 10 includes a main board 15 and a connector 13, attached to a front end of the main board 15. A mounting hole 11 is defined in a central portion of the main board 15. A pair of arc-shaped gaps 14 is defined in the main board 15 and located at opposite sides of the main board 15. The connector 13 includes a pair of pins 12 extending through the main board 15 and protruding from a rear side of the main board 15.

The shielding member 20 is a rectangular hollow structure. The shielding member 20 includes an entrance opening 21 at a front end of the shielding member 20. A rear end of the shielding member 20 is closed. The shielding member 20 includes a side panel 23. A mounting opening 231 is defined in the side panel 23 and located adjacent to the entrance opening 21.

The latch member 30 includes a main panel 31 and a covering portion 33 attached to a front end of the main panel 31. A plurality of engaging posts 315 protrudes from an inner side of the main panel 31, corresponding to the mounting hole 11 and the pair of arc-shaped gaps 14. An opening 314 is defined in the main panel 31 and located adjacent to the covering portion 33. The main panel 31 includes a resilient arm 311 located in the opening 314. A wedge-shaped protrusion 313 protrudes from a free end of the resilient arm 311 and is located adjacent to the covering portion 33, for engaging with the mounting opening 231. The covering portion 33 includes a first side wall 331 and a pair of second side walls 333 extending substantially perpendicularly from opposite sides of the first side wall 331. The first side wall 331 protrudes from an outside of the main panel 31 and is substantially parallel to the main panel 31. The pair of second side walls 333 abuts opposite sides of the main panel 31. A distance between the pair of second side walls 333 is greater than a width of the main board 15. An exterior surface of the resilient arm 311 lies in the same plane as an outer surface of the main panel 31. A thickness of the resilient arm 311 is less than the thickness of the main panel 31.

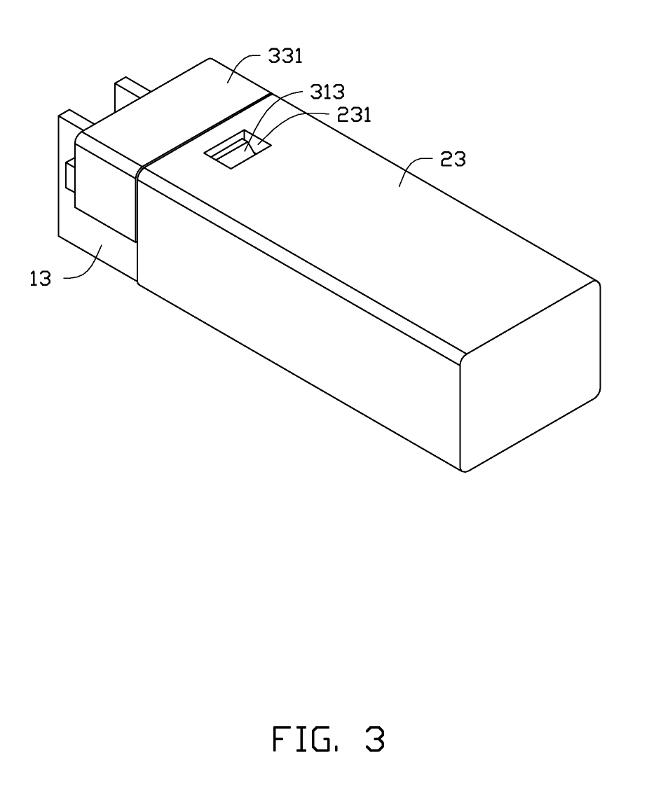

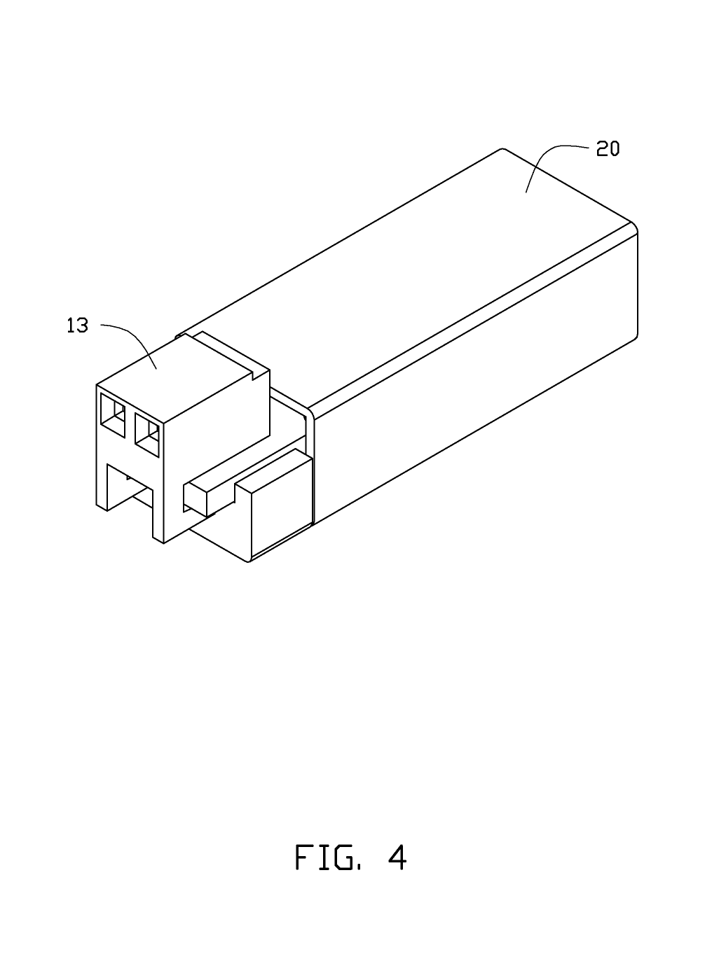

Referring to FIGS. 3 and 4, in assembly, the plurality of engaging posts 315 is engaged in the mounting hole 11 and the pair of arc-shaped gaps 14. The front end of the main board 15 is located between the pair of second side walls 333. The latch member 30 is attached to the rear side of the circuit board 10. The main panel 31 abuts against the main board 15. The first side wall 331 is located above the pair of pins 12 and shields the pair of pins 12. The circuit board 10 and the latch member 30 are inserted into the shielding member 20 via the entrance opening 21. The wedge-shaped protrusion 313 is pressed by the side panel 23. The resilient arm 311 is deformed until the wedge-shaped protrusion 313 reaching the mounting opening 231. The wedge-shaped protrusion 313 engages with a front edge of the mounting opening 231 and prevents the circuit board 10 disengaging from the shielding member 20. The covering portion 33 abuts the front end of the shielding member 20. The first side wall 331 lies in the same plane as the side panel 23. Each of the pair of second side walls 333 lies in the same plane as a sidewall of the shielding member 20. A main portion of the circuit board 10 is received in the shielding member 20. The connector 13 at the front end of the circuit board 10 is located on the outside of the shielding member 20, available for engaging with a mating connector of another circuit board.

To detach the circuit board 10 from the shielding member 20, the wedge-shaped protrusion 313 is pressed down to be disengaged from the front edge of the mounting opening 231. The latch member 30 and the circuit board 10 can be pulled out from the shielding member 20.

While the present disclosure has been illustrated by the description in this embodiment, and while the embodiment has been described in detail, it is not intended to restrict or in any way limit the scope of the appended claims to such details. Additional advantages and modifications within the spirit and scope of the present disclosure will readily appear to those skilled in the art. Therefore, the present disclosure is not to be limited to the specific details and illustrative examples shown and described.

What is claimed is:

1. A circuit board assembly comprising:
a circuit board comprising a main board and a connector attached to one end of the main board, at least one mounting hole is defined in the main board, and at least one pin protrudes from the main board;
a latch member attached to the circuit board, the latch member comprises a main panel abutting the main board, at least one engaging post engages the at least one mounting hole, and a covering portion attached to one end of the main panel for covering the at least one pin; and
a shielding member for accommodating the circuit board and the latch member and protecting the circuit board;
wherein main portions of the main board and the main panel are received in the shielding member, and the connector and the covering portion are exposed out of the shielding member.

2. The circuit board assembly of claim 1, wherein an opening is defined in the main panel, the main panel comprises a resilient arm received in the opening, and a blocking protrusion protrudes from a distal end of the resilient arm; and a mounting opening is defined in the shielding member for engaging with the blocking protrusion.

3. The circuit board assembly of claim 2, wherein the shielding member has a rectangular-shaped hollow structure, and the mounting opening is defined in a side panel of the shielding member and located adjacent to a front end of the shielding member.

4. The circuit board assembly of claim 3, wherein the shielding member comprises an entrance opening at the front end of the shielding member, and a rear end of the shielding member is closed.

5. The circuit board assembly of claim 4, wherein the covering portion comprises a first side wall and a pair of second side walls extending substantially perpendicularly from opposite sides of the first side wall, and the first side wall is located above the at least one pin for shielding the at least one pin.

6. The circuit board assembly of claim 5, wherein the pair of second side wall abut opposite sides of the main panel, and the main board is located between the pair of second side wall.

7. The circuit board assembly of claim 6, wherein the first side wall and the pair of second side walls abut the front end of the shielding member, the first side wall lies in the same plane as the side panel, and each of the pair of second side walls lies in the same plane as a corresponding sidewall of the shielding member.

8. The circuit board assembly of claim 2, wherein an exterior surface of the resilient arm lies in the same plane as an outer surface of the main panel, and a thickness of the resilient arm is less than the thickness of the main panel.

9. The circuit board assembly of claim 1, wherein the connector protrudes at a front side of the main board, and the at least one pin extends through the main board and protrudes at a rear side of the main board.

10. A circuit board assembly comprising:
a circuit board with at least one mounting hole defined therein, at least one pin extends through the circuit board and protrudes from the circuit board;
a latch member attached to the circuit board, the latch member comprises a main panel abutting the circuit board, at least one engaging post engages the at least one mounting hole, a covering portion attached to one end of the main panel for shielding the at least one pin, and a resilient arm; and
a shielding member, configured for accommodating the circuit board and the latch member and shielding the circuit board, comprising a side panel with a mounting opening defined therein;
wherein the resilient arm is movable between a natural state, where a distal end of the resilient arm is engaged with an edge of the mounting opening for preventing the circuit board disengaging from the shielding member, and a deformed state, where the distal end of the resilient arm is disengageable from the mounting opening to allow detachment of the circuit board from the shielding member.

11. The circuit board assembly of claim 10, wherein the circuit board comprises a main board and a connector attached to one end of the main board, main portions of the main board and the main panel are received in the shielding member, and the connector and the covering portion are exposed out of the shielding member.

12. The circuit board assembly of claim 11, wherein an opening is defined in the main panel, the resilient arm is received in the opening, and a blocking protrusion protrudes from a distal end of the resilient arm for engaging with the mounting opening.

13. The circuit board assembly of claim 12, wherein the shielding member has a rectangular-shaped hollow structure and comprises a side panel, and the mounting opening is defined in the side panel and located adjacent to a front end of the shielding member.

14. The circuit board assembly of claim 13, wherein the shielding member comprises an entrance opening at the front end of the shielding member, and a rear end of the shielding member is closed.

15. The circuit board assembly of claim 14, wherein the covering portion comprises a first side wall and a pair of second side walls extending substantially perpendicularly from opposite sides of the first side wall, and the first side wall is located above the at least one pin for shielding the at least one pin.

16. The circuit board assembly of claim 15, wherein the pair of second side wall abuts against opposite sides of the main panel, and the main board is located between the pair of second side wall.

17. The circuit board assembly of claim 16, wherein the first side wall and the pair of second side walls abut against the front end of the shielding member, the first side wall lies in the same plane as the side panel, and each of the pair of second side walls lies in the same plane as a corresponding sidewall of the shielding member.

18. The circuit board assembly of claim 10, wherein an exterior surface of the resilient arm lies in the same plane as an outer surface of the main panel, and a thickness of the resilient arm is less than the thickness of the main panel.
